(19) United States
(12) Patent Application Publication
(10) Pub. No.: US 2017/0039961 A1
(43) Pub. Date: Feb. 9, 2017

(54) SYSTEMS AND METHODS FOR FACILITATING REPAIR OF INOPERABLE MEMS DISPLAY ELEMENTS

(71) Applicant: Pixtronix, Inc, San Diego, CA (US)

(72) Inventor: Teruo Sasagawa, Los Gatos, CA (US)

(21) Appl. No.: 14/817,039

(22) Filed: Aug. 3, 2015

(51) Int. Cl. G09G 3/34; B81C 1/00; G09G 3/20

(52) U.S. Cl. CPC G09G 3/3433; G09G 3/2003; G09G 3/2022; B81C 1/00341

(57) ABSTRACT

This disclosure provides systems, methods, and apparatus for facilitating repair of inoperable MEMS display elements. A display apparatus can include a plurality of display elements over a substrate. Each display element can have a pixel output interconnect. The display apparatus also can include a plurality of conductive bridges each associated with the pixel output interconnects of a respective pair of adjacent display elements. A first conductive bridge can include an electrical connection between the pixel output interconnects of a first pair of adjacent display elements. A second conductive bridge associated with a second pair of adjacent display elements can be electrically isolated from the pixel output interconnects of at least one display element of the second pair of display elements. A laser or other means can be used to form an electrical connection between the first conductive bridge and the respective pair of adjacent display elements.

### TECHNICAL FIELD

This disclosure relates to the field of imaging displays, and to light modulators incorporated into imaging displays.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, or a combination of these or other micromachining processes that etch away parts of substrates, the deposited material layers, or both. Such processes may also be used to add layers to form electrical and electromechanical devices.

EMS-based display apparatus can include display elements that modulate light by selectively moving a light blocking component into and out of an optical path through an aperture defined through a light blocking layer. Defective display elements that are unable to block light can reduce image quality and manufacturing yield.

### SUMMARY

The systems, methods and devices of this disclosure each have several innovative aspects, no single one of which is solely responsible for the desirable attributes disclosed herein.

One innovative aspect of the subject matter described in this disclosure can be implemented in a display device. The display device can include a plurality of MEMS display elements positioned over a substrate. Each display element can include a pixel output interconnect and a pixel control circuit. For at least a first display element, a pixel control circuit of the first display element can be electrically isolated from a pixel output interconnect of the first display element, and a first conductive bridge can form an electrical connection between the pixel output interconnect of the first display element and a pixel output interconnect of a second display element adjacent the first display element.

In some implementations, a voltage applied to the pixel output interconnect of the first display element can be based at least in part on a data signal provided to the second display element. In some implementations, at least a portion of the first conductive bridge can be positioned closer to a rear surface of the display device than a pixel output interconnect of at least one of its respective pair of adjacent display elements. In some implementations, at least a portion of the first conductive bridge can be positioned closer to a front surface of the display device than at least one of the pixel output interconnect of the first display element and the pixel output interconnect of the second display element. In some implementations, the first conductive bridge can be within an aperture layer suspended above the plurality of display elements.

In some implementations, each display element can include a respective shutter including an electrically conductive structural material. The first conductive bridge can include the same conductive material as the shutters of the plurality of display elements. In some implementations, the electrically conductive structural material can include amorphous silicon. In some implementations, the display device can include a second conductive bridge associated with a third display element and a fourth display element adjacent the third display element. The second conductive bridge can be separated from the pixel output interconnect of the third display element and the pixel output interconnect of the fourth display element by a dielectric material. In some implementations, the display device can include a light blocking layer positioned above or below the plurality of MEMS display elements and the first conductive bridge. The light blocking layer can include at least one optical aperture aligned with an intersection of the first conductive bridge and the pixel output interconnect of the first display element or a load anchor associated with the first display element. In some implementations, each of the plurality of display elements can be associated with at least one conductive bridge.

In some implementations, the display device can include a processor capable of communicating with the display device. The processor can be capable of processing image data. The display device also can include a memory device capable of communicating with the processor. In some implementations, the display device can include a driver circuit capable of sending at least one signal to the display device and a controller capable of sending at least a portion of the image data to the driver circuit. In some implementations, the display device can include an image source module capable of sending the image data to the processor. The image source module can include at least one of a receiver, transceiver, and transmitter. In some implementations, the display device can include an input device capable of receiving input data and communicating the input data to the processor.

Another innovative aspect of the subject matter described in this disclosure can be implemented in a method of repairing a display device. The method can include forming a plurality of display elements over a substrate. Each display element can include a pixel control circuit and a pixel output interconnect. The method can include forming a plurality of conductive bridges associated with the pixel output interconnects of adjacent display elements. The method can include identifying at least one inoperable display element of the plurality of display elements. The at least one inoperable display element can be unable to respond to a data signal applied by its respective pixel control circuit. The method can include electrically isolating the pixel control circuit of the at least one inoperable display element from the pixel output interconnect of the at least one inoperable display element. The method can include electrically connecting one of the conductive bridges to the pixel output interconnect of the at least one inoperable display element and the pixel output interconnect of an adjacent display element.

In some implementations, electrically isolating the pixel control circuit of the at least one inoperable display element from the pixel output interconnect of the at least one inoperable display element can include ablating a portion of the pixel output interconnect of the at least one inoperable display element to cut the pixel output interconnect of the at least one inoperable display element. In some implementations, electrically connecting one of the conductive bridges to the pixel output interconnect of the at least one inoperable display element and the pixel output interconnect of an adjacent display element can include directing electromagnetic radiation at the conductive bridge. The electromagnetic radiation can ablate a dielectric material separating the conductive bridge from the pixel output interconnects of the at least one inoperable display element and the adjacent display element. The electromagnetic radiation also can melt a portion of the conductive bridge or the pixel output interconnects of the at least one inoperable display element and the adjacent display element such that the melted portion fills a space previously occupied by the ablated dielectric material to form an electrical connection between the conductive bridge and the pixel output interconnects of the at least one inoperable display element and the adjacent display element.

In some implementations, forming the plurality of conductive bridges can include forming the conductive bridges within an aperture layer of the display device. In some implementations, the method can include forming a light blocking layer above or below the plurality of display elements and the plurality of conductive bridges, and forming at least one optical aperture in the light blocking layer. The at least one optical aperture can be aligned with an intersection of a conductive bridge and a pixel output interconnect of a display element. In some implementations, forming the plurality of display elements can include forming a respective shutter associated with each display element. The shutters can include an electrically conductive structural material. Forming the plurality of conductive bridges also can include forming at least one conductive bridge from the same conductive material as the shutters. In some implementations, each of the plurality of display elements can be associated with at least one conductive bridge.

Another innovative aspect of the subject matter described in this disclosure can be implemented in a method of repairing a display device. The display device can include a plurality of MEMS display elements positioned over a substrate. Each display element can include an output voltage carrying means and a control means. A control means of the first display element can be electrically isolated from an output voltage carrying means of the first display element. A first conductive means can form an electrical connection between the output voltage carrying means of the first display element and an output voltage carrying means of a second display element adjacent the first display element.

In some implementations, a voltage applied to the output voltage carrying means of the first display element can be based at least in part on a data signal provided to the second display element. In some implementations, the first conductive means can be within an aperture layer suspended above the plurality of MEMS display elements. In some implementations, each display element can include a respective light blocking means including an electrically conductive structural material. The first conductive means can include the same conductive material as the light blocking means of the plurality of display elements. In some implementations, the electrically conductive structural material can include amorphous silicon.

In some implementations, the display device can include a second conductive means associated with a third display element and a fourth display element adjacent the third display element. The second conductive means can be separated from the output voltage carrying means of the third display element and the output voltage carrying means of the fourth display element by a dielectric material. In some implementations, the display device can include a light blocking layer positioned above or below the plurality of MEMS display elements and the first conductive means. The light blocking layer can include at least one optical aperture aligned with an intersection of the first conductive means and the output voltage carrying means of the first display element or a load anchor associated with the first display element. In some implementations, each of the plurality of MEMS display elements can be associated with at least one conductive means.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIG. 3A shows a top view of an example display device including an inoperable display element.

FIG. 3B shows a top view of the example display device of FIG. 3A after a repair operation has been performed to electrically connect the inoperable display element to an adjacent functional display element.

FIG. 4 shows an example schematic diagram of an inoperable display element electrically coupled to an adjacent functional display element.

FIG. 5A shows a top view of an example display element.

FIG. 5B shows a top view of the example display element shown in FIG. 5A incorporating an elevated aperture layer.

FIG. 6A shows a top view of two example display elements adjacent to one another.

FIG. 6B shows a cross sectional view along the line A-A′ shown in FIG. 6A prior to a repair operation.

FIG. 6C shows a cross sectional view along the line A-A′ shown in FIG. 6A after the repair operation.

FIG. 6D shows a first example cross sectional view along the line B-B′ shown in FIG. 6A prior to a repair operation.

FIG. 6E shows a first example cross sectional view along the line B-B′ shown in FIG. 6A after the repair operation.

FIG. 6F shows a second example cross sectional view along the line B-B′ shown in FIG. 6A prior to a repair operation.

FIG. 6G shows a second example cross sectional view along the line B-B′ shown in FIG. 6A after the repair operation.

FIG. 7A shows a top view of two example display elements adjacent to one another.

FIG. 7B shows a cross sectional view along the line C-C′ shown in FIG. 7A prior to a repair operation.

FIG. 7C shows a cross sectional view along the line C-C′ shown in FIG. 7A after the repair operation.

FIG. 8A shows a top view of two example display elements adjacent to one another.

FIG. 8B shows a cross sectional view along the line D-D′ shown in FIG. 8A prior to a repair operation.

FIG. 8C shows a cross sectional view along the line D-D′ shown in FIG. 8A after the repair operation.

FIG. 9 shows a flow chart of an example process of repairing a display device.

FIG. 10 shows a portion of an example pixel control circuit.

FIGS. 11A and 11B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

A display device can produce images by modulating light using an array of pixels. In some implementations, the array of pixels can include MEMS display elements. Fabrication of such arrays can sometimes result in limited numbers of display elements that are non-responsive to data signals provided to the circuits supplied to control the state of the display elements, referred to as “pixel control circuits.” Non-responsive display elements are sometimes referred to as “inoperable display elements.” In some cases, the non-responsiveness can be due to errors in fabricating pixel circuitry associated with the display elements. Because inoperable display elements may not respond correctly to data signals, the quality of images produced by a display device having inoperable display elements can be reduced. An inoperable display element can be repaired, and image quality improved, by electrically coupling a portion of the inoperable display element to a pixel control circuit of an adjacent, functional display element. Such a repair may not allow the inoperable display element to be individually addressed; however, image quality can be enhanced by driving the inoperable display element into the same state as the adjacent functional display element.

To allow for the repair of inoperable display elements, conductive bridges can be provided between pairs of adjacent display elements. A conductive bridge can include an electrically isolated interconnect positioned above or below the pixel output interconnects of two adjacent display elements. In some implementations, the conductive bridges can be formed from the same layer of material used to form the structural components of the display elements. In some other implementations, the conductive bridges can be formed from a metal layer separated from the structural layers by a dielectric material.

When one of the pair of adjacent display elements is determined to be inoperable, the display element can be disconnected from its respective pixel output interconnect and connected to the pixel output interconnect of its neighboring pixel by the conductive bridge. In some implementations, the inoperable display element can be disconnected from its pixel output interconnect by use of a laser or other source of electromagnetic radiation to sever the electrical connection from the pixel output interconnect to the inoperable display element. The conductive bridge also can be connected to both the inoperable display element and the adjacent functional display element by use of a laser. For example, a laser can be directed at the locations where the conductive bridge overlaps the circuitry associated with the inoperable display element and the adjacent, functional display element. The laser can ablate the dielectric material separating the conductive bridge from the pixel control circuits and can melt a portion of the of the conductive bridge, which then fills the space previously occupied by the ablated dielectric to form an electrical connection. As a result, signals provided to the functional display element can traverse the conductive bridge to drive the inoperable display element. The inoperable display element is therefore driven into the same state as the adjacent, functional display element.

Particular implementations of the subject matter described in this disclosure can be implemented to realize one or more of the following potential advantages. Driving an inoperable display element into the same state as an adjacent display element can improve image quality. For example, inoperable display elements can be conspicuous when they are surrounded by functional display elements whose brightness levels are uniform or near-uniform, yet significantly different from the brightness level of the inoperable display element. This type of image defect can be mitigated by driving inoperable display elements into the same state as their neighboring display elements. Furthermore, adjacent display elements often are intended to be driven into the same state to display an image, particularly when the image has relatively low spatial variation. Thus, driving inoperable display elements into the same state as their neighboring display elements often can result in the inoperable display elements achieving their intended brightness level, or a brightness level close to their intended brightness level, despite not being individually addressable.

Incorporating conductive bridges between adjacent display elements in a display device can help to improve yield for production of display devices. Typically, a display device must meet minimum image quality parameters before being provided to an end-user, however the presence of inoperable display elements can prevent a display device from meeting such minimum image quality parameters. In some cases, an inoperable display element can be repaired by electrically connecting the inoperable display element to an adjacent, functional display element. Thus the image quality of display devices having inoperable display elements can be improved, thereby improving overall yield for production of display devices.

In some implementations, the cost of producing displays incorporating conductive bridges can be reduced by using MEMS structural layers to form the conductive bridges. In some display devices, space within the metal layers that form the backplane of the display device is limited, making it difficult to create conductive bridges within the existing metal layers. This is particularly true for high resolution display devices. Adding additional metal layers within the backplane for the conductive bridges can increase the cost and complexity of manufacturing. However, in some implementations, forming conductive bridges within the MEMS structural layers deposited over the backplane can be done with little to no increase in the process cost.

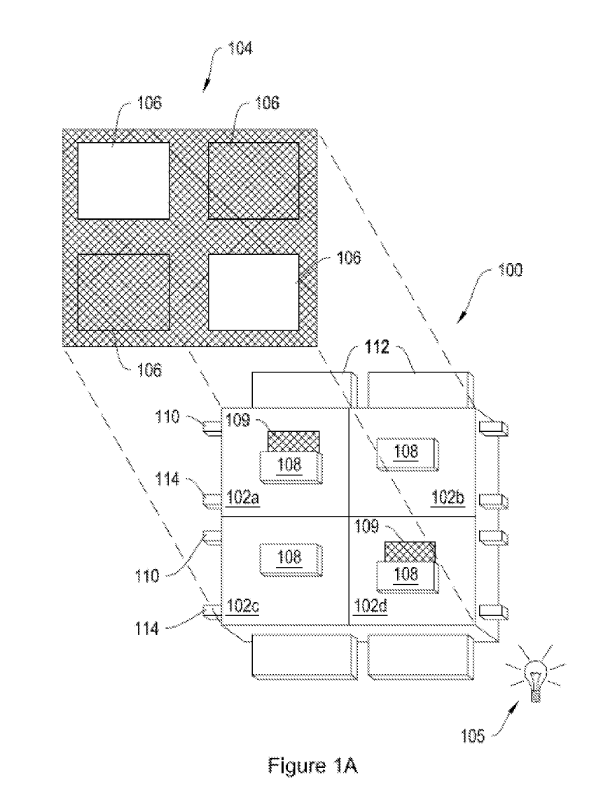

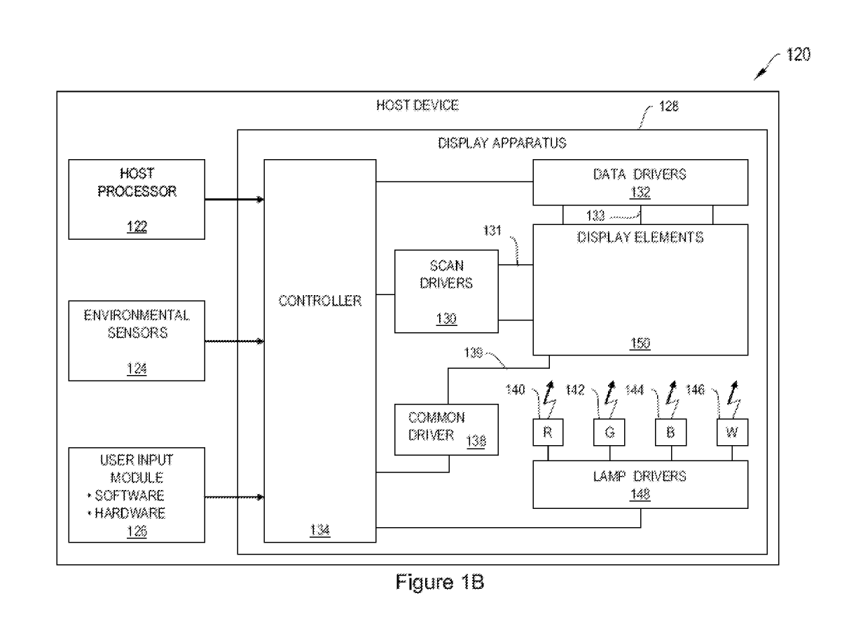

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness of the display, the contrast of the display, or both.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for a certain fraction of the image is loaded to the array of display elements 150. For example, the sequence can be implemented to address every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; instructions for the display apparatus 128 for use in selecting an imaging mode; or any combination of these types of information.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

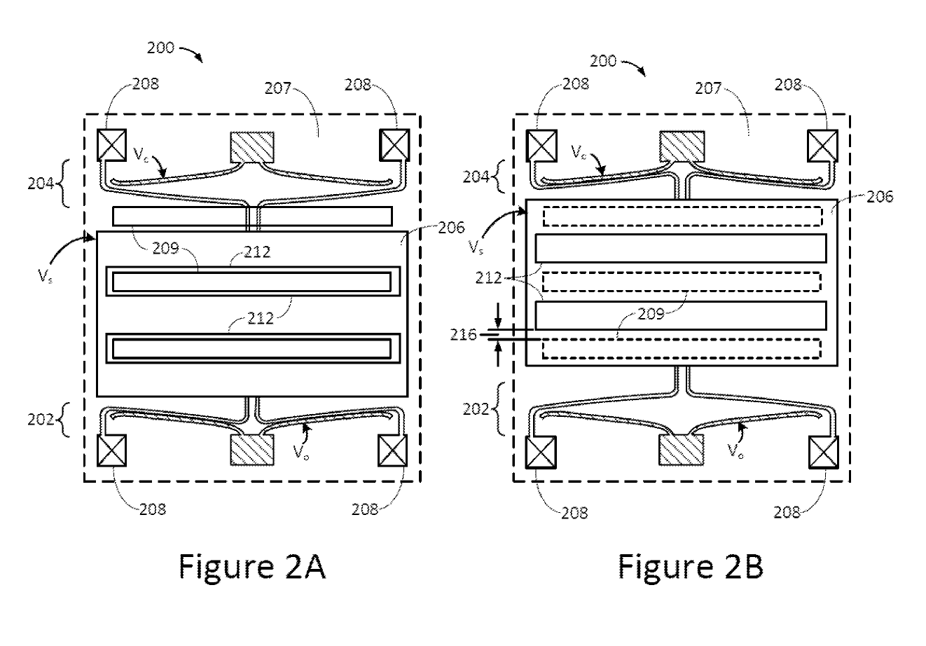

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

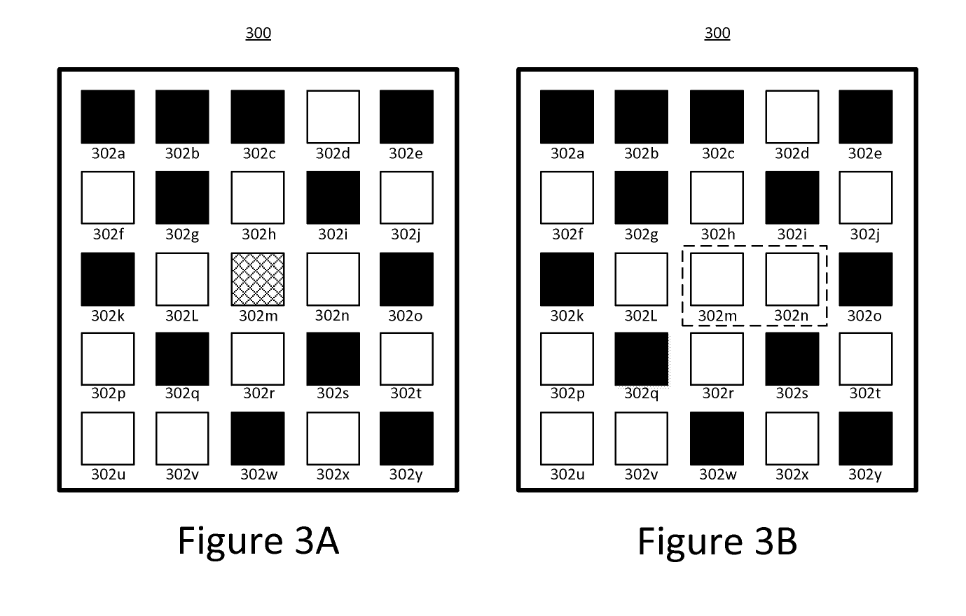

FIG. 3A shows a top view of an example display device 300 including an inoperable display element. The display device 300 includes an array of display elements 302a-302y (generally referred to as display elements 302) arranged in rows and columns. Each display element 302 can be driven into an open state in which the display element 302 passes light, or a closed state in which the display element 302 blocks light. As shown in FIG. 3A, some of the display elements 302 are in an open state, represented by white squares, while others in a closed state, represented by black squares. Together, the display elements 302 can be used to form images on the display device 300. For illustrative purposes, the display device 300 is shown as including a relatively small number of display elements 302. However, it should be understood that in practice the display device 300 may include many thousands or millions of display elements 302.

Also shown in FIG. 3A is an inoperable display element 302m. The inoperable display element 302m is shown with a cross-hatch pattern to indicate that the state of the inoperable display element 302m is unknown. In some implementations, the inoperable display element 302m may be stuck in an intermediate state (i.e., neither an open state nor a closed state). In some other implementations, the inoperable display element 302m may be stuck in either an open state or a closed state, and is unable to transition to a different state. In some implementations, the inoperable display element 302m may be unable to respond to a data signal applied to the pixel control circuit controlling the state of the inoperable display element 302m. The display element 302m may become inoperable due to a defect arising within the manufacturing process. For example, one or more of the components included in the pixel control circuit of the display element, such as a transistor, may not be fully operational, or one or more interconnects within the pixel control circuit may have become broken or shorted to other components. In some implementations, the display device 300 may include more than one inoperable display element 302. However, the percentage of display elements 302 that are inoperable is typically small.

The inoperable display element 302m can negatively impact the quality of images produced by the display device 300. For example, when the inoperable display element 302m is stuck in an intermediate state or in any state that does not correspond to the image data for the display element 302m, the human visual system may recognize a defect in the image produced by the display device 300. In some cases, such a defect can be particularly apparent when the inoperable display element 302m is stuck in an open position while the pixels surrounding the inoperable 302m are in a closed state. The degradation of image quality that results from the inoperable display element 302m can be mitigated by electrically connecting the inoperable display element 302m to an adjacent, functional display element.

FIG. 3B shows a top view of the example display device 300 of FIG. 3A after a repair operation has been performed to electrically connect the inoperable display element 302m to an adjacent functional display element 302n. The dotted lines surrounding the display elements 302m and 302n indicate that the display elements 302m and 302n are connected such that they are both driven into the same state in each image frame. As shown, the inoperable display element 302m is no longer in an unknown state because it is driven along with its neighboring display element 302n. Thus, although the inoperable display element 302m is not individually addressable, it is able to change its state according to the image data provided to the adjacent display element 302n. It should be understood that in some implementations, the inoperable display element 302m can instead be electrically connected to a different adjacent display element 302. For example, the inoperable display element 302m can instead be connected to any one of its adjacent display elements 302h, 302l, and 302r.

Electrically connecting the inoperable display element 302m to the adjacent, functional display element 302n (or any one of its other adjacent display elements 302) can help to improve image quality. For example, because the display elements 302 each represent a very small portion of an image, it is often the case that the intensity variation across adjacent display elements 302 within each image frame is relatively small. Therefore, driving the inoperable display element 302m into the same state as the adjacent display element 302n can allow the inoperable display element 302m to achieve a brightness level that is close to its intended brightness level, where the intended brightness level is determined by the actual image data for the inoperable display element 302m. Electrically connecting the inoperable display element 302m to the adjacent display element 302n also helps to prevent the inoperable display element 302m from producing a brightness level that varies significantly from brightness level of the surrounding display elements 302, which could result in a more apparent image defect.

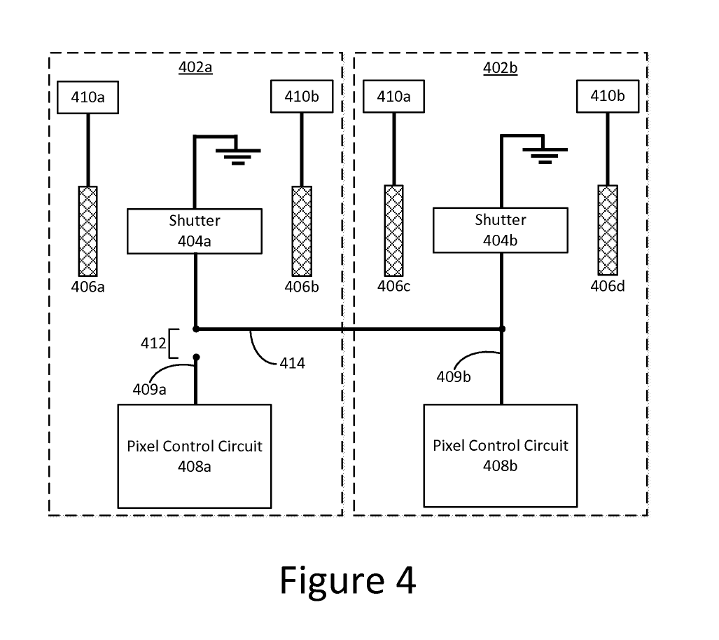

FIG. 4 shows an example schematic diagram of a repaired, previously inoperable display element 402a coupled to an adjacent functional display element 402b. The normal operation and structure of a functional display element will be described with reference to the functional display element 402b. The display element 402b includes a shutter 404b electrically connected to a pixel control circuit 408b by a pixel output interconnect 409b. The shutter 404b is positioned between a shutter close electrode 406c and a shutter open electrode 406d. The shutter close electrode 406c receives a voltage from a global shutter close voltage source 410a. The shutter open electrode 406d receives a voltage from a global shutter open voltage source 410b. In some implementations, the voltage supplied to the shutter close electrode 406c can be a low voltage (i.e., about 0V), and the voltage applied to the shutter open electrode 406d can be a high voltage (i.e., a voltage in the range of about 15V to 20V). The pixel control circuit 408b supplies a voltage to the shutter 404b to cause the shutter to move towards either the shutter close electrode 406c or the shutter open electrode 406d. For example, the pixel control circuit 408b can supply a low voltage to the shutter 404b to cause the shutter 404b to move towards the shutter open electrode 406d by electrostatic force. Similarly, the pixel control circuit 408b can supply a high voltage to the shutter 404b to cause the shutter 404b to move towards the shutter close electrode 406c by electrostatic force. In some other implementations, the voltage supplied to the shutter open electrode 406d can be a low voltage and the voltage supplied to the shutter close electrode 406c can be a high voltage, and the actuation voltages supplied to the shutter 404b by the pixel control circuit 408b also can be reversed accordingly. In some implementations, the polarity of the shutter close electrode 406c and the shutter open electrode 406d may vary over time. For example, the polarity of the shutter close electrode 406c and the shutter open electrode 406d can be switched in each image frame, and the pixel control circuit 408b can adjust the voltages supplied to the shutter 404b accordingly. The shutter 404b moves between the shutter close electrode 406c and the shutter open electrode 406d above an aperture formed in an underlying light blocking layer to modulate light.

The repaired inoperable display element 402a includes components similar to the components of the display element 402b. For example, the inoperable display element 402a includes a shutter 404a positioned between a shutter close electrode 406a and a shutter open electrode 406b. The shutter close electrode 406a receives a voltage from the global shutter close voltage source 410a and the shutter open electrode 406b receives a voltage from the global shutter open voltage source 410b. The inoperable display element 402a also includes a pixel control circuit 408a. However, as part of a repair process, the pixel output interconnect 409a that would typically couple the pixel control circuit 408a to the shutter 404a has been severed, as indicated by the opening 412 in the pixel output interconnect 409a. The shutter 404a of the inoperable display element 402a also has been electrically connected to the pixel output interconnect 409b of the display element 402b by the interconnect 414.

Cutting the pixel output interconnect 409a to electrically isolate the shutter 404a from the pixel control circuit 408a of the inoperable display element 402a can help to improve the performance of the inoperable display element 402a after the inoperable display element 402a has been electrically connected to the functional display element 402b. For example, while the pixel control circuit 408a may not be fully functional, it may still output voltages that could interfere with the voltage received by the shutter 404a from the pixel control circuit of 408b of the adjacent functional display element 402b. In some implementations, the pixel output interconnect 409a of the inoperable display element 402a can be cut by directing electromagnetic radiation, such as radiation output by a laser, at the pixel output interconnect 409a. A laser also can be used to fuse the interconnect 414 to the pixel output interconnect 409b of the display element 402b and to the portion of the pixel output interconnect 409a that remains connected to the shutter 404a of the inoperable display element 402a.

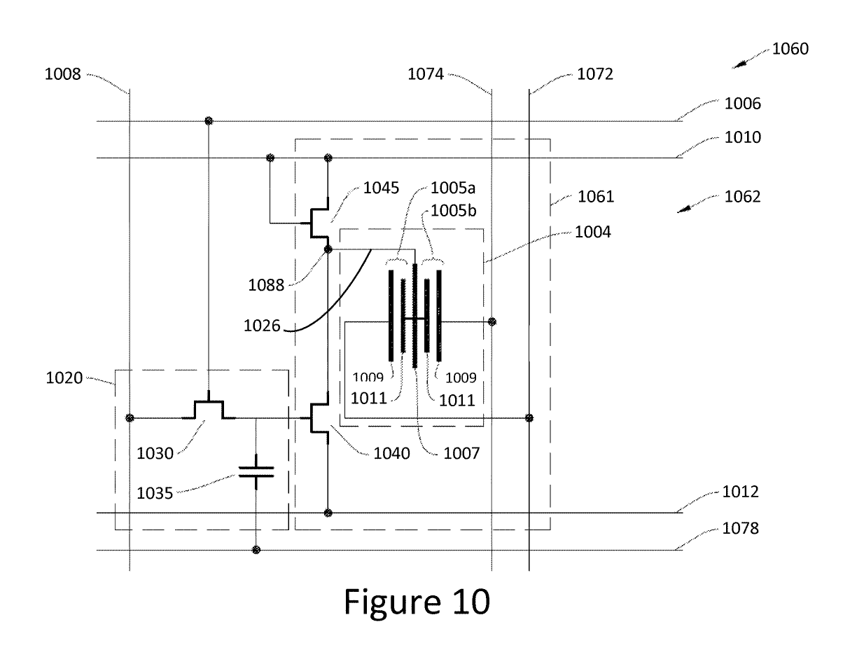

In some implementations, the interconnect 414 can be implemented as a conductive bridge that is initially fabricated to be electrically isolated from the pixel output interconnect 409a and the pixel output interconnect 409b. After it has been determined that the display element 402a is inoperable, the interconnect 414 can be electrically connected to the pixel output interconnect 409a and the pixel output interconnect 409b so that the shutter 404a can be driven by the pixel control circuit 408b. In some implementations, such a conductive bridge can be formed from structural materials such as those used to form the shutters 404a and 404b. In some other implementations, a conductive bridge can be formed from underlying metal layers that may be included within a backplane of the display device. A more detailed pixel control circuit diagram for the display elements 402a and 402b is discussed further in connection with FIG. 10.

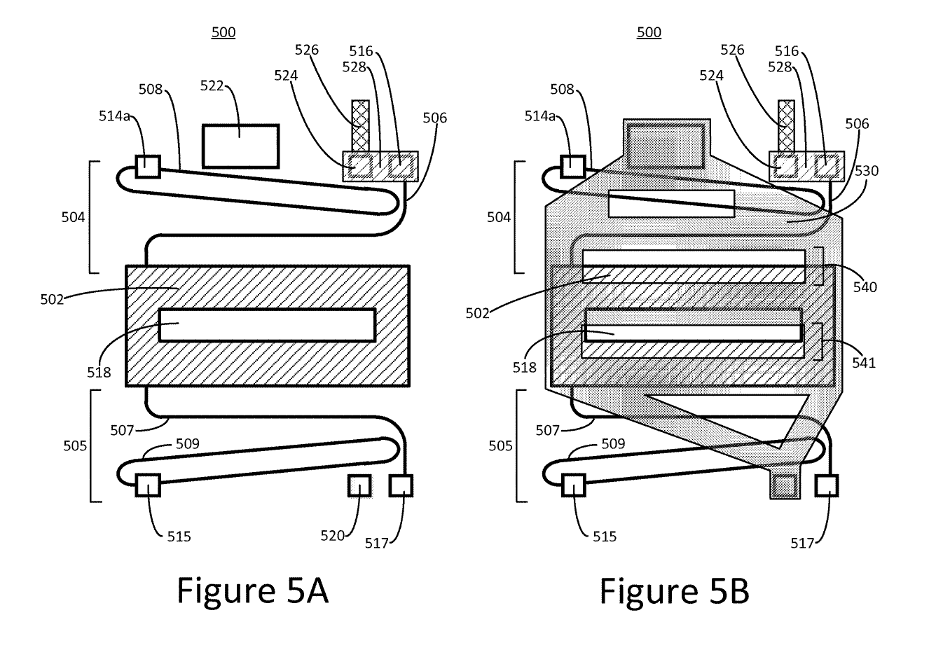

FIG. 5A shows a top view of an example display element 500. The display element 500 includes a shutter 502 and two actuators 504 and 505. The actuator 504 is an electrostatic actuator including a load beam 506 that is fixed at one end to an edge of the shutter 502 and at another end to a load anchor 516. The actuator also includes a drive beam 508. The drive beam 508 is shaped as a loop arranged at an angle with respect to the shutter 502. A drive anchor 514 mechanically couples the drive beam 508 to an underlying substrate over which the shutter 502 and the actuators 504 and 505 are suspended. The load anchor 516 couples the load beam 506 to the underlying substrate. The load beam 506 extends along substantially the entire length of the drive beam 508.

The actuator 505 is arranged on a side of the shutter 502 opposite to the side on which the actuator 504 is arranged, and includes components similar to those described above with respect to the actuator 504. For example, the actuator 505 includes a load beam 507 coupled at one end to the shutter 502 and at the other end to a load anchor 517. The actuator 505 also includes a drive beam 509. A drive anchor 515 couples the drive beam 509 to the underlying substrate. The load anchor 517 couples the load beam 507 to the substrate.

The position of the shutter 502 is controlled by the actuators 504 and 505, in a manner similar to the actuation process described above in connection with FIG. 4. For example, an actuation voltage can be applied across the drive beam 508 and the load beam 506 of the actuator 504. The actuation voltage creates an electrostatic force that tends to draw the drive beam 508 and the load beam 506 together. Because one end of the drive beam 508 is fixed to the substrate by the drive anchor 514, the electrostatic force causes the load beam 506 to move towards the drive beam 508. As the load beam 506 moves, the shutter 502 also moves toward the drive beam 508 while remaining substantially parallel to the underlying substrate, because the load beam 506 is fixed to the edge of the shutter 502. The actuator 505 operates in substantially the same manner as the actuator 504, except that it is configured to pull the shutter 502 in the opposite direction. Therefore, by selectively applying actuation voltages to actuators 504 and 505, the position of the shutter 502 can be controlled.

The display element 500 also includes a pixel output interconnect 526 coupled at one end to an anchor 524. The pixel output interconnect 526 can be formed from a metal layer deposited onto the underlying substrate. A second end of the pixel output interconnect 526 couples to additional circuitry (not shown in FIG. SA) of the pixel control circuit, configured to receive a data voltage for the display element 500 and set an output voltage on the pixel output interconnect 526 accordingly. The anchor 524 is coupled to the load anchor 516 by an interconnect 528. The load anchor 516 in turn is electrically coupled to the shutter 502 by the load beam 506. Thus, an output voltage can be provided to the shutter via an electrical path through the pixel output interconnect 526, the anchor 524, the interconnect 528, the load anchor 516, and the load beam 506. In some implementations, the drive beam 508 can be supplied with a constant low voltage and the drive beam 509 can be supplied with a constant high voltage. An appropriate voltage can then be supplied to the shutter 502 to cause the shutter 502 to move towards either of the drive beams 508 and 509, as discussed above in connection with FIG. 4. Anchors 520 and 522 are provided to support an elevated aperture layer (EAL), as described further below in connection with FIG. 5B.

The shutter 502 includes an aperture 518 through which light can pass when the aperture 518 is aligned with an aperture formed in an underlying light blocking layer. Thus, by modulating the position of the shutter 502 using the actuators 504 and 505, the amount of light that is permitted to pass by the shutter 502 can be controlled. This light can represent a single pixel of an image on a display in which the display element 500 is incorporated. In practice, a display device may include thousands or millions of light display elements similar to the display element 500, in order to form a full image.

FIG. 5B shows a top view of the example display element 500 shown in FIG. 5A incorporating an EAL 530. The EAL 530 can be supported by the 520 and 522 shown in FIG. 5A. The EAL 530 includes an apertures 540 and 541 that are aligned with apertures formed in an underlying light blocking layer. When the shutter 502 is in an open position (i.e., pulled toward the drive beam 509), the shutter aperture 518 is aligned with the EAL aperture 541 and the shutter 502 does not obstruct the EAL aperture 540, allowing light to pass through the apertures in the underlying light blocking layer as well as the EAL apertures 540 and 541. When the shutter 502 is in a closed position (i.e., pulled toward the drive beam 508), the shutter 502 obstructs both of the EAL apertures 540 and 541 as well as the corresponding apertures in the underlying light blocking layer, prevent light from passing.

The EAL 530 can block extraneous light that would otherwise exit the display device at high angles. In some implementations, the shutter 502, as well as the components of the actuators 504 and 505, can be formed by depositing a structural material over a sacrificial mold. The EAL 530 can be formed from an additional layer of structural material deposited over a second mold formed over the shutter 502. In some implementations, the same material used to form shutter 502 also can be used to form the EAL 530.

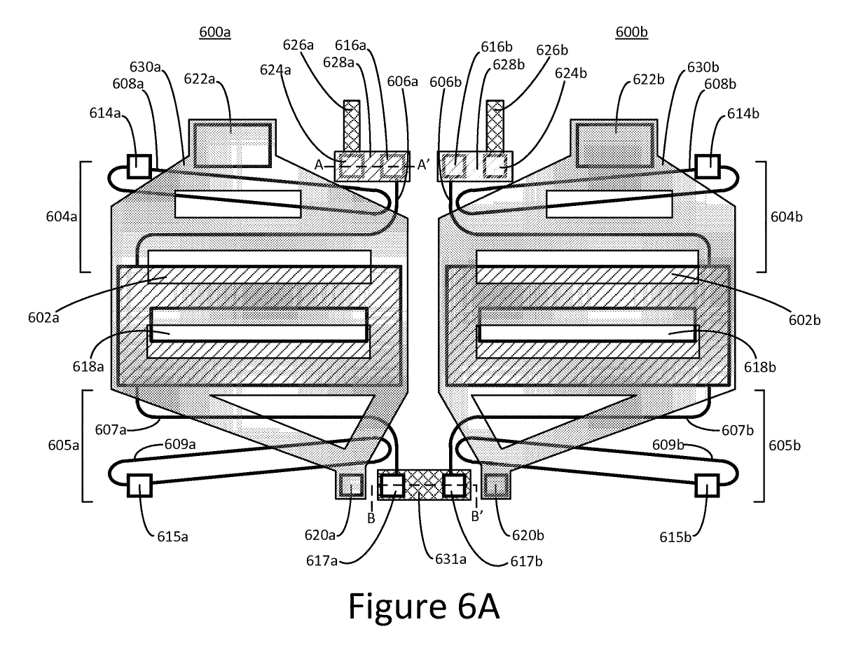

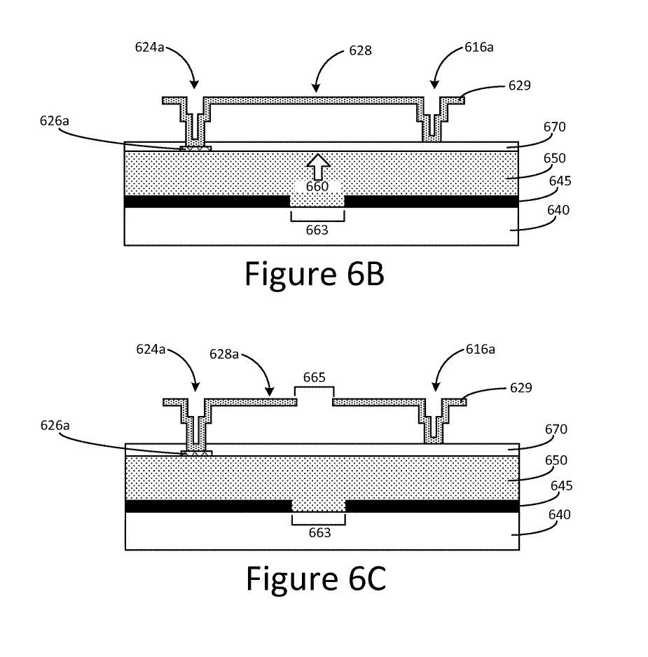

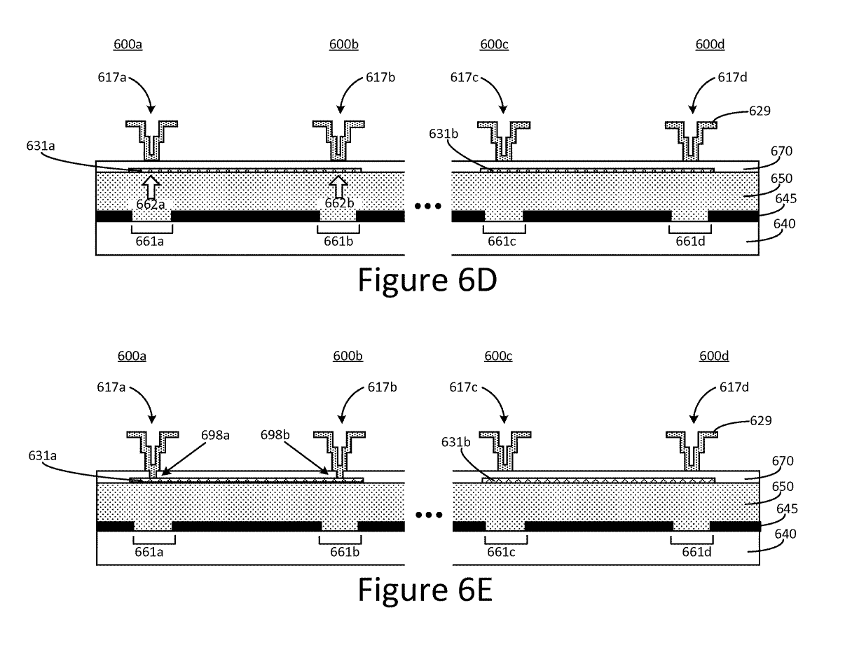

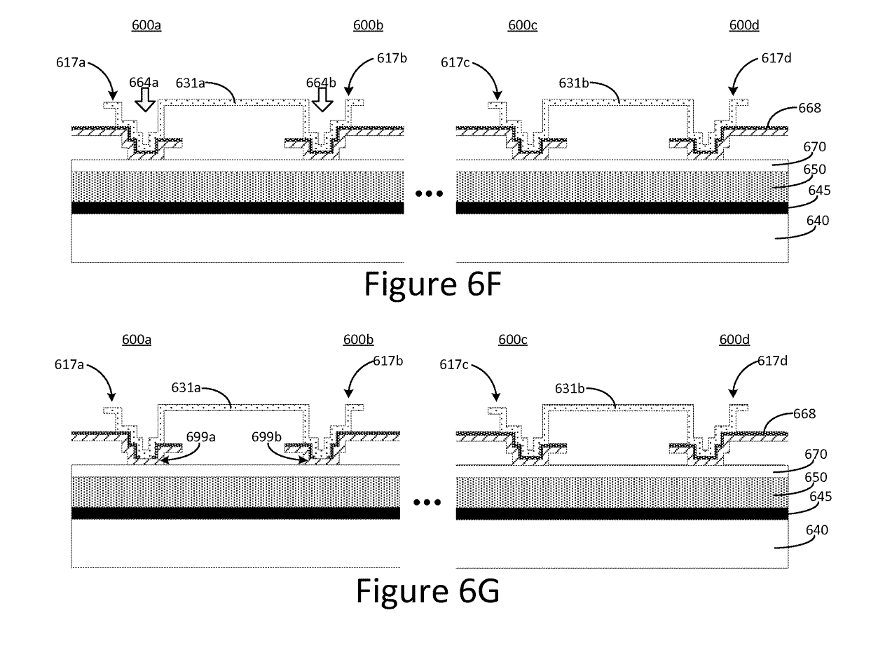

FIG. 6A shows a top view of two example display elements 600a and 600b (generally referred to as display elements 600) adjacent to one another. The display elements 600 include components similar to the components described above in connection with the display element 500 shown in FIGS. 5A and 5B, and like reference numerals refer to like elements. In FIG. 6A, the EALs 630a and 630b are shown as partially transparent for illustrative purposes, however in practice, the EALs 630a and 630b can be substantially opaque in order to block light. The orientation of the display element 600b is a mirror image of the orientation of the display element 600a. In some implementations, such an arrangement can allow for closer spacing of the display elements 600 and also can facilitate the process of electrically connecting the display element 600a to the display element 600b, if one of the display elements 600 is determined to be inoperable.

Also shown in FIG. 6A is a conductive bridge 631. The conductive bridge 631 can be positioned above or beneath the load anchors 617a and 617b. In some implementations, the conductive bridge 631 is formed from a metal layer within a backplane on the underlying substrate beneath the display elements 600. A dielectric material (not shown in FIG. 6A) can electrically isolate the conductive bridge 631 from each of the load anchors 617a and 617b.

In some implementations, one of the display elements 600 may be inoperable, for example due to a defect arising within the manufacturing process. For purposes of the discussion of FIGS. 6A-6E, it will be assumed that the display element 600a is inoperable. No physical defect can be seen in the display element 600a, however a defect in the associated circuitry that drives the display element 600a may still render the display element 600a inoperable. As discussed above, it may be desirable to electrically connect the inoperable display element 600a to the functional display element 600b. More particularly, establishing an electrical connection between the display elements 600 such that the shutter 602a of the display element 600a receives output voltages provided to the shutter 602b of the display element 600b can help to mitigate the reduction of image quality that would otherwise result from the display element 600a being inoperable. In some implementations, this electrical connection can be made via the conductive bridge 631.

The load anchors 617a and 617b are electrically connected to their respective shutters 602a and 602b via their respective load beams 607a and 607b. Thus, an electrical connection formed between the load anchors 617a and 617b allows the shutter 602a of the inoperable display element 600a to receive the output voltages applied to the shutter 602b of the functional display element 600b. This electrical connection can be formed by the conductive bridge 631, for example, by removing the dielectric material that separates the conductive bridge 631 from the load anchors 617a and 617b and coupling the conductive bridge 631 directly to the load anchors 617a and 617b. The electrical connection between the shutter 602a of the inoperable display element and its associated inoperable pixel control circuit also can be severed to improve the reliability of the repaired inoperable display element 600a. The process used to electrically isolate the inoperable display element 600a from its respective inoperable drive circuitry is described further below in connection with FIGS. 6B and 6C. The process used to electrically connect the shutter 602a of the inoperable display element 600a to the shutter 602b of the functional display element 600b is described further below in connection with FIGS. 6D and 6E.

FIG. 6B shows a cross sectional view along the line A-A′ shown in FIG. 6A prior to a repair operation. A light blocking layer 645 is formed over a substrate 640. The light blocking layer 645 can include light blocking material that can substantially block the passage of light through the light blocking layer 645. In some implementations, the light blocking material can be a light absorbing material such as carbon-black or titanium-black. In some other implementations, the light blocking material can be a light reflective material such as silver (Ag), aluminum (Al), or copper (Cu) for reflecting light. In some other implementations, the light blocking layer 645 can include a combination of light absorbing and light reflecting material. In some other implementations, the light blocking material can include an interferometric optical reflection or optical absorption layer, which may include one or more layers of dielectric films, metals, semiconductors, or a combination of dielectric films, semiconductors, and metals. In some other implementations, the light blocking material can be a dark spin-on glass. A backplane 650 is formed over the light blocking layer 645. The backplane 650 can include circuitry, such as pixel control circuits, for driving the display elements formed over the substrate 640. While the backplane 650 is shown as a single element, it should be understood that the backplane 650 may include several layers of material deposited over the light blocking layer 645. For example, layers of conductive material, semiconducting material, and dielectric material may be deposited over the light blocking layer 645 and etched to define circuitry forming the backplane 650. For illustrative purposes, the pixel output interconnect 626a is labeled in FIGS. 6B and 6C as a separate element from the backplane 650, but it should also be understood that the pixel output interconnect 626a is generally considered to be a component of the backplane 650.

The pixel output interconnect 626a can be formed from a layer of conductive material, such as a metal layer or a transparent conductor such as indium-tin-oxide (ITO) that has been etched to form interconnects including the pixel output interconnect 626a. The load anchor 616a, the interconnect 628a, and the anchor 624a are formed from one or more layers of conductive structural material 629 positioned over the backplane 650. In some implementations, the structural material 629 can include a metal, such as titanium (Ti) or aluminum (Al). In some other implementations, the structural material 629 can include amorphous silicon (a-Si). In some other implementations, the structural material 629 can include multiple layers of metal and dielectric films. For example, the structural material 629 can include alternating layers of silicon nitride (SiNx) and Ti or alternating layers of silicon dioxide (SiO2) and Ti. In some other implementations, the structural material 629 can include metal layers such as Ti or Al positioned between a layer of SiNx and a layer of a-Si. As shown, the anchor 624a is in direct contact with the pixel output interconnect 626a so that the anchors 624a can receive an output voltage from an associated pixel control circuit through the pixel output interconnect 626a. The load anchor 616a is positioned over the dielectric material 655, and is therefore electrically isolated from the conductive layers of the underlying backplane 650. However, the load anchor 616a is able to receive the output voltage supplied by the pixel output interconnect 626a via the interconnect 628a.

Also shown in FIG. 6B is an optical window 663 formed in the light blocking layer 645. The optical window 663 provides an optical path from the substrate 640 to the interconnect 628. In some implementations, the backplane 650 also can be formed from transparent materials that do not interrupt these optical paths. If the backplane 650 includes layers of opaque materials, such as metals, these opaque materials can be etched away in the regions aligned with the optical window 663 formed in the light blocking layer 645, so that they do not obstruct the optical path.

As discussed above, the shutter 602a shown in FIG. 6A is electrically connected to the load anchor 616a through the load beam 606a. Therefore, the interconnect 628a can be severed in order to electrically isolate the shutter 602b from the pixel output interconnect 626a. This can be achieved, for example, by directing laser light, represented by the arrow 660, towards the interconnect 628a through the optical window 663. The laser light 660 can be selected to have a power sufficient to ablate or otherwise sever a portion of the interconnect 628a without substantially affecting the load anchor 616a, the anchor 624a, or the underlying backplane 650. In some other implementations, a different technique can be used to ablate a portion of the interconnect 628a. For example, another form of electromagnetic radiation can be directed at the interconnect 628a to ablate a portion of the interconnect 628a.

FIG. 6C shows a cross sectional view along the line A-A′ shown in FIG. 6A after the repair operation. As shown, a gap 665 is formed in the interconnect 628a, thereby electrically isolating the load anchor 616a (and therefore the shutter 602a) from the pixel output interconnect 626a. As a result, the shutter 602a will no longer receive output voltages supplied to the pixel output interconnect 626a by an associated pixel control circuit. It should be understood that other interconnects similar to the pixel output interconnect 626a and the interconnect 628a may be present at other locations within the display element 600a, and therefore these interconnects may also require severing in order to electrically isolate the shutter 602a from the pixel control circuit. Such additional interconnects can be severed in a manner similar to that shown in FIGS. 6B and 6C.

In some implementations, the display elements 600 can be included within a display that incorporates a front substrate, a rear substrate, and a back light positioned behind the rear substrate. The back light can include a rear reflective layer that does not allow light to pass. As a result, there may not be an optical path through the rear substrate of the device that could permit optical access for the laser to carry out the repair operation discussed above after the display device has been assembled. Thus, in implementations in which the display elements are formed on the front substrate of the display device (referred to as a MEMS-down configuration), the optical window 663 can provide an optical path through the front of the assembled display device. This arrangement can allow the laser repair operation to be carried out after the display device has been fully assembled.

In some other implementations, the repair operation may be carried out by directing laser light at the interconnect 628 through a front substrate, rather than the rear substrate 640. For example, a back light can include a light guide that does not allow light to pass—for example its rear surface may be coated with an opaque material. As a result, there may not be an optical path through the rear substrate 640 that could permit optical access for the laser to carry out the repair operation discussed above after the display device has been assembled. Thus, in implementations in which the display elements are formed on the rear substrate of the display device (referred to as a MEMS-up configuration), optical windows such as the optical window 663 may not be effective, because the optical path from outside the display device is still interrupted by the back light. Instead, optical windows can be provided in a light blocking layer formed over the EALs 630a and 630b to provide an optical path through the front of the assembled display device. This arrangement can allow the laser repair operation to be carried out after the display device has been fully assembled. This arrangement also can allow greater freedom in the design and layout of circuitry in the backplane 650, because there is no need for an optical path through the backplane 650.

FIG. 6D shows a first example cross sectional view along the line B-B′ shown in FIG. 6A prior to a repair operation. As shown, e load anchor 617a of the inoperable display element 600a and the load anchor 617b of the functional display element 600b are formed over the underlying layers described above in connection with FIGS. 6B and 6C. The conductive bridge 631a spans the distance between the load anchor 617a and the load anchor 617b. As shown in FIG. 6D, prior to the repair operation, the load anchors 617a and 617b are electrically isolated from one another, and the dielectric layer 670 electrically isolates the conductive bridge 631a from both of the load anchors 617a and 617b. FIG. 6D also shows an adjacent pair of load anchors 617c and 617d, each associated with a respective display element 600c and 600d included in the same display device as the display elements 600a and 600b. A conductive bridge 631b is positioned beneath the load anchors 617c and 617d, and is separated from the load anchors 617c and 617d by the layer of dielectric material 670. For purposes of the following discussion, it is assumed that the display elements 600cand 600d associated with the load anchors 617c and 617d, respectively, are both fully operational and therefore do not need to undergo any repair operation.

Also shown in FIG. 6D are optical windows 661a and 661b formed in the light blocking layer 645. The optical window 661a is aligned with the load anchor 617a, while the optical window 661b is aligned with the load anchor 617b. The optical windows 661a and 661b provide optical paths from the substrate 640 to the conductive bridge 631a. In some implementations, the backplane 650 also can be formed from transparent materials that do not interrupt these optical paths. If the backplane 650 includes layers of opaque materials, such as metals, these opaque materials can be etched away in the regions aligned with the optical windows 661a and 661b formed in the light blocking layer 645, so that they do not obstruct the optical paths. Optical windows 661c and 661d also are formed in the light blocking layer 645 beneath the load anchors 617c and the load anchor 617d, respectively.

The conductive bridge 631a can be used to electrically connect the load anchor 617a of the inoperable display element 600a to the load anchor 617b of the display element 600b. For example, laser light represented by the arrow 662a can be directed through the optical window 661a formed in the light blocking layer 645 towards the intersection of the conductive bridge 631a and the load anchor 617a. Similarly, laser light represented by the arrow 662b can be directed through the optical window 661b formed in the light blocking layer 645 towards the intersection of the conductive bridge 631a and the load anchor 617b. The laser light 662a and 662b can be absorbed by the conductive bridge 631a, causing its temperature to rise. This temperature increase can ablate the dielectric material 670 in the regions where the load anchors 617a overlap with the conductive bridge 631a, as well as cause the materials forming the conductive bridge 631a and the load anchors 617a and 617b to melt in these regions. The melted material can fill the space previously occupied by the ablated dielectric material 670, thereby electrically connecting the load anchors 617a and 617b to the conductive bridge 631a. It is not necessary to perform the laser repair operation on the display elements associated with the load anchors 617c and 617d, because these display elements are both fully operational. Therefore, the load anchor 617c and the load anchor 617d both remain electrically isolated from the conductive bridge 631b.

FIG. 6E shows a first example cross sectional view along the line B-B′ shown in FIG. 6A after the repair operation. As shown, the dielectric material 670 has been removed in regions beneath the load anchors 617a and 617b, and the load anchors 617a and 617b are now in direct contact with the conductive bridge 631a at the points labeled 698a and 698b, respectively. Because the load anchors 617a and 617b are electrically connected to each other through the conductive bridge 631a, and are electrically connected to their respective shutters 602a and 602b through their respective load beams 607a and 607b, the shutter 602a of the inoperable display element 600a is able to receive the output voltage applied to the shutter 602b of the functional display element 600b. As a result, the inoperable display element 600a can be driven into the same state as the functional display element 600b, which can help to improve image quality. Because the display elements associated with the load anchors 617c and 617d are both fully operational, the laser repair operation has not been performed on either of these display elements. As a result, the conductive bridge 631b remains electrically isolated from the load anchors 617c and 617d.

As discussed above in connection with FIGS. 6B and 6C, in some implementations the repair operation can be performed by directing laser light through the opposite side of the display device. In such an implementation, optical windows can be formed in a light blocking layer positioned above the EALs 630a and 630b to provide an optical path to the anchors 617a and 617b, respectively. Laser light can be directed along these optical paths through the optical windows formed in a light blocking layer positioned above the EALs 630a and 630b, thereby electrically connecting the load anchors 617a and 617b to the conductive bridge 631a. The optical windows 661a and 661b formed in the light blocking layer 645 may not be necessary in such an arrangement.

FIG. 6F shows a second example cross sectional view along the line B-B′ shown in FIG. 6A prior to a repair operation. In contrast to the first example cross sectional view shown in FIGS. 6D and 6E, the second example cross sectional view of FIG. 6F shows the conductive bridge 631a positioned above the load anchors 617a and 617b. As shown, the load anchor 617a of the inoperable display element 600a and the load anchor 617b of the functional display element 600b are formed over the underlying layers described above in connection with FIGS. 6B and 6C. The conductive bridge 631a spans the distance between the load anchor 617a and the load anchor 617b. As shown in FIG. 6F, prior to the repair operation, the load anchors 617a and 617b are electrically isolated from one another, and the dielectric layer 668 electrically isolates the conductive bridge 631a from both of the load anchors 617a and 617b. FIG. 6F also shows an adjacent pair of load anchors 617c and 617d, each associated with a respective display element included in the same display device as the display elements 600a and 600b. A conductive bridge 631b is positioned above the load anchors 617c and 617d, and is separated from the load anchors 617c and 617d by the layer of dielectric material 668. For purposes of the following discussion, it is assumed that the display elements associated with the load anchors 617c and 617d are both fully operational and therefore do not need to undergo any repair operation.

The conductive bridge 631a can be used to electrically connect the load anchor 617a of the inoperable display element 600a to the load anchor 617b of the display element 600b. For example, laser light represented by the arrow 664a can be directed towards the intersection of the conductive bridge 631a and the load anchor 617a. Similarly, laser light represented by the arrow 664b can be directed towards the intersection of the conductive bridge 631a and the load anchor 617b. The laser light 664a and 664b can be absorbed by the conductive bridge 631a, causing its temperature to rise. This temperature increase can ablate the dielectric material 668 in the regions where the load anchors 617a and 617b overlap with the conductive bridge 631a, as well as cause the materials forming the conductive bridge 631a and the load anchors 617a and 617b to melt in these regions. The melted material can fill the space previously occupied by the ablated dielectric material 668, thereby electrically connecting the load anchors 617a and 617b to the conductive bridge 631a. As described above, because the laser light 664a and 664b is directed at the conductive bridge 631a from a position above the conductive bridge 631a, no optical windows are necessary in the underlying layers. It is not necessary to perform the laser repair operation on the display elements associated with the load anchors 617c and 617d, because these display elements are both fully operational. Therefore, the load anchor 617c and the load anchor 617d both remain electrically isolated from the conductive bridge 631b.

FIG. 6G shows a second example cross sectional view along the line B-B′ shown in FIG. 6A after the repair operation. As shown, the dielectric material 668 has been removed in regions above the load anchors 617a and 617b, and the load anchors 617a and 617b are now in direct contact with the conductive bridge 631a at the points labeled 699a and 699b, respectively. Because the load anchors 617a and 617b are electrically connected to each other through the conductive bridge 631a, and are electrically connected to their respective shutters 602a and 602b through their respective load beams 607a and 607b, the shutter 602a of the inoperable display element 600a is able to receive the output voltage applied to the shutter 602b of the functional display element 600b. As a result, the inoperable display element 600a can be driven into the same state as the functional display element 600b, which can help to improve image quality. Because the display elements associated with the load anchors 617c and 617d are both fully operational, the laser repair operation has not been performed on either of these display elements. As a result, the conductive bridge 631b remains electrically isolated from the load anchors 617c and 617d.

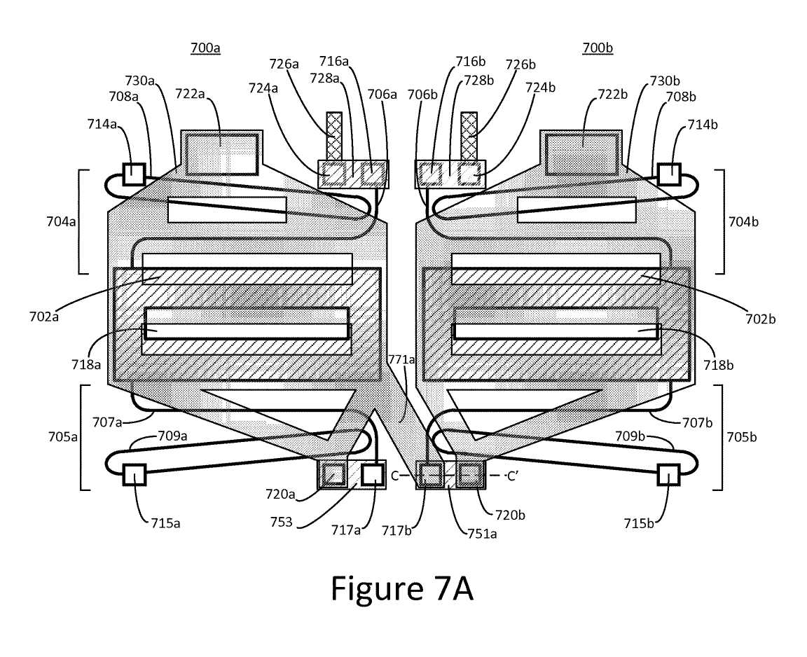

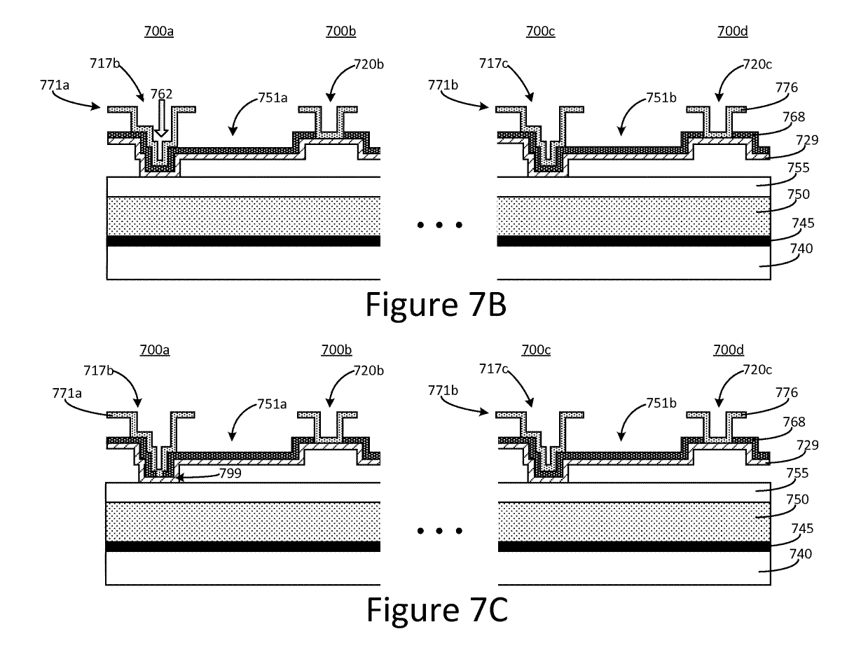

FIG. 7A shows a top view of two example display elements 700a and 700b (generally referred to as display elements 700) adjacent to one another. The display elements 700 include components similar to the components described above in connection with the display element 500 shown in FIGS. 5A and 5B, as well as the display elements 600 shown in FIG. 6A, and like reference numerals refer to like elements. Display elements 700a and 700b include the EALs 730a and 730b, which are shown as partially transparent for illustrative purposes; however in practice, the EALs 730a and 730b can be substantially opaque in order to block light.

Also shown in FIG. 7A are an interconnect 751a that electrically couples the load anchor 717b to the EAL anchor 720b and an interconnect 753 that electrically couples the load anchor 717a to the EAL anchor 720a. The interconnects 751a and 753 can be formed from the same layer of material used to form the shutters 702a and 702b. The EAL 730a of the display element 700a has a modified shape that includes a conductive bridge 771a which extends over the load anchor 717b of the adjacent display element 700b. A dielectric material (not shown in FIG. 7A) can electrically isolate the conductive bridge 771a from the load anchor 717b.

In some implementations, one of the display elements 700 may be inoperable, for example due to a defect arising within the manufacturing process. For purposes of the discussion of FIGS. 7A-7C, it will be assumed that the display element 700a is inoperable. Establishing an electrical connection between the display elements 700 such that the shutter 702a of the inoperable display element 700a receives output voltages provided to the shutter 702b of the display element 700b can help to mitigate the reduction of image quality that would otherwise result from the display element 700a being inoperable, as discussed above. In some implementations, this electrical connection can be made by the conductive bridge 771a. In some implementations, the interconnect 728a also can be severed to electrically isolate the display element 700a from the pixel output interconnect 726a in a process similar to that shown in FIGS. 6B and 6C.

FIG. 7B shows a cross sectional view along the line C-C′ shown in FIG. 7A prior to a repair operation. The cross-sectional view of FIG. 7B shows many of the components described above in connection with FIGS. 6B-6E, and like reference numerals refer to like elements. For example, a light blocking layer 745 is formed over a substrate 740. A backplane 750 is formed over the light blocking layer 745. The EAL anchor 720b and the load beam anchor 717b, are positioned over the backplane 750.

A first layer of structural material 729 is positioned over the substrate 740 to form the shutters 702 as well as the load anchor 717b. A layer of insulating material 768 is positioned over the first layer of structural material 729, and a second layer of structural material 776 is positioned over the layer of insulating material 768 to form the EALs 730a and 730b and the EAL anchor 720b shown in FIG. 7A. A portion of the insulating material 768 positioned over the EAL anchor 720b is removed so that the second layer of structural material 776 positioned over the EAL anchor 720b is in direct contact with the first layer of structural material 729. As a result, the EAL 730b shown in FIG. 7A is electrically connected to the load anchor 717b. This can help to prevent attraction between the shutter 702b and the EAL 730b, because both are maintained at the same potential and therefore do not exert electrostatic forces on one another. FIG. 7B also shows a load anchor 717c and an EAL anchor 720c, each associated with a respective display element 700c and 700d included in the same display device as the display elements 700a and 700b. A conductive bridge 771b is positioned beneath the load anchors 717c, and is separated from the load anchor 717c by the layer of insulating material 768. For purposes of the following discussion, it is assumed that the display elements 700c and 700d associated with the load anchor 717c and the EAL anchor 720c, respectively, are both fully operational and therefore do not need to undergo any repair operation.

The conductive bridge 771a is formed over the load anchor 717b, but is electrically isolated from the load anchor 717b by the insulating material 768. In order to electrically connect the shutter 702a of the inoperable display element 700a to the shutter 702b of the functional display element 700b, laser light represented by the arrow 762 can be directed at the load anchor 717b. The laser light 762 can ablate the insulating material 768 and melt the structural materials 729 and 776 in the region of load anchor 717b. As a result, the melted structural materials 729 and 776 can flow into the space previously occupied by the ablated insulating material 768, thereby forming an electrical connection between the conductive bridge 771a and the load anchor 717b. In some implementations, an additional light blocking layer can be formed over the EALs 730a and 730b. In order to provide optical access to the load anchor 717b, the additional light blocking layer can include optical windows aligned with the load anchor 717b, so that the laser light 762 is not obstructed by the additional light blocking layer. In some implementations, the power of the laser light 762 can be selected such that it is sufficiently high to melt the structural materials 729 and 776 and to ablate the insulating material 768, but is also sufficiently low to avoid melting, vaporizing, or otherwise destroying the structural material 729. It is not necessary to perform the laser repair operation on the display elements associated with the load anchor 717c and the EAL anchor 720c, because these display elements are both fully operational. Therefore, the load anchor 717c remains electrically isolated from the conductive bridge 771b.

FIG. 7C shows a cross sectional view along the line C-C′ shown in FIG. 7A after the repair operation. As shown, the insulating material 768 has been removed in the region aligned with the load anchor 717b, and the material forming the conductive bridge 771a is in direct contact with the load anchor 717b at the point labeled 799. The load anchor 717b is electrically connected to the shutter 702b through the load beam 707b. The conductive bridge 771a is electrically connected to the shutter 702a through the EAL 730a, the interconnect 753, the load anchor 717a, and the load beam 707a. An electrical path is therefore established between the shutter 702b and the shutter 702a. As a result, the inoperable display element 700a can be driven into the same state as the functional display element 700b, which can help to improve image quality. Because the display elements associated with the load anchor 717c and the EAL anchor 720c are both fully operational, the laser repair operation has not been performed on either of these display elements. As a result, the conductive bridge 771b remains electrically isolated from the load anchor 717c.

As discussed above, the display elements 700 can be included within a display that incorporates a front substrate, a rear substrate, and a back light positioned behind the rear substrate. In implementations in which the display elements are formed on the rear substrate of the display device (referred to as a MEMS-up configuration), optical windows such as the optical window 663 shown in FIG. 6B may not be effective, because the optical path from outside the display device is still interrupted by the back light. Instead, optical windows can be provided in a light blocking layer formed over the EALs 730a and 730b, as discussed above, to provide an optical path through the front of the assembled display device. This arrangement can allow the laser repair operation to be carried out after the display device has been fully assembled.

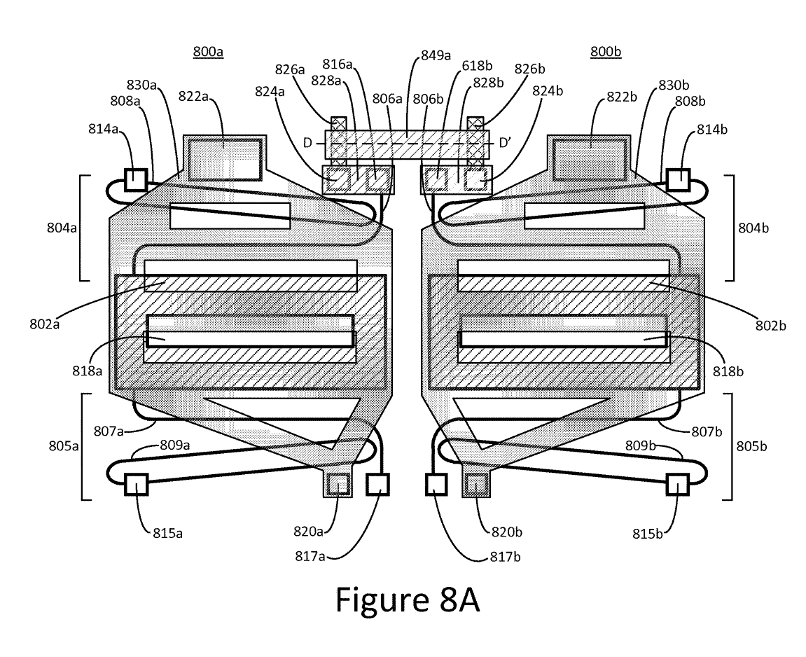

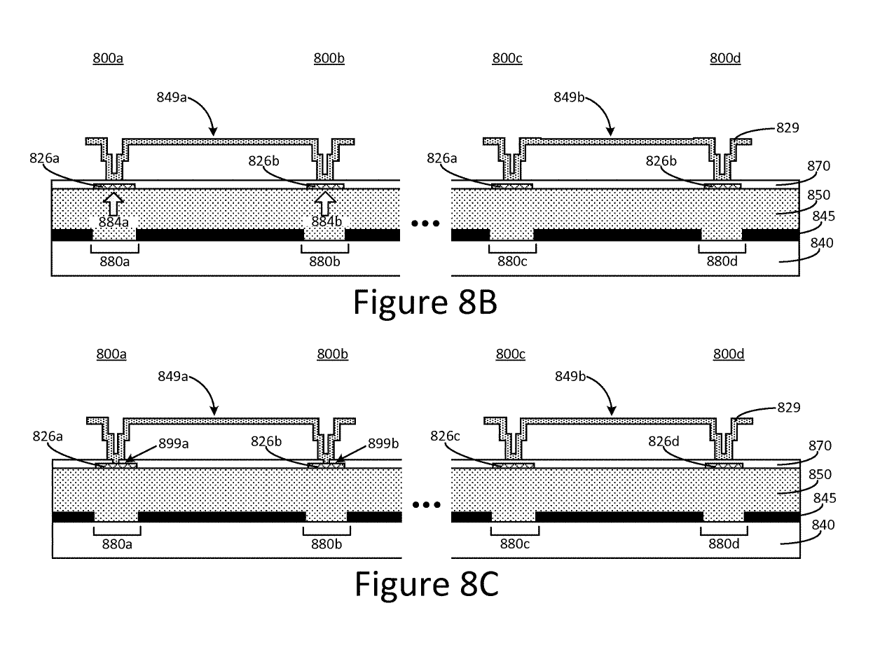

FIG. 8A shows a top view of two example display elements 800a and 800b (generally referred to as display elements 800) adjacent to one another. The display elements 800 include components similar to the components described above in connection with the display element 500 shown in FIGS. 5A and 5B as well as the display elements 600 shown in FIG. 6A, and like reference numerals refer to like elements. The EALs 830a and 830b are shown as partially transparent for illustrative purposes; however, in practice, the EALs 830a and 830b can be substantially opaque in order to block light.

Also shown in FIG. 8A is a conductive bridge 849a. The conductive bridge 849a is positioned above the pixel output interconnects 826a and 826b. In some implementations, the conductive bridge 849a is formed from the same layer of structural material used to form the shutters 802a and 802b of the display elements 800. A dielectric material (not shown in FIG. 8A) can electrically isolate the conductive bridge 849a from each of the load pixel output interconnects 826a and 826b.

In some implementations, one of the display elements 800 may be inoperable, for example due to a defect arising within the manufacturing process. For purposes of the discussion of FIGS. 8A-8C, it will be assumed that the display element 800a is inoperable. As discussed above, establishing an electrical connection between the display elements 800 such that the shutter 802a of the inoperable display element 800a receives voltages provided to the shutter 802b of the display element 800b can help to mitigate the reduction of image quality that would otherwise result from the display element 800a being inoperable. In some implementations, this electrical connection can be made by the conductive bridge 849a and the pixel output interconnects 826a and 826b. In some implementations, the pixel output interconnect 826a also can be severed to electrically isolate the inoperable display element 800a from its associated pixel control circuit.

It should be noted that a process similar to the process used to isolate the inoperable display element 600a from its associated pixel control circuit as shown in FIGS. 6B and 6C should be avoided if the display elements 800 are to be electrically connected through the conductive bridge 849a. Because the pixel output interconnects 826a and 826b are to be electrically coupled by the conductive bridge 849a, severing the interconnect 828a would prevent an electrical connection from being formed between the display elements 800. Therefore, the inoperable display element 800a should instead be isolated from its pixel control circuit in another way, for example, by severing a portion of the pixel output interconnect 826a located between the conductive bridge 849a and the pixel control circuit.

FIG. 8B shows a cross sectional view along the line D-D′ shown in FIG. 8A prior to a repair operation. The cross-sectional view shows many of the components described above in connection with FIGS. 6B-6E, and like reference numerals refer to like elements. For example, a light blocking layer 845 is formed over a substrate 840. Optical windows 880a and 880b are formed in the light blocking layer 845 in regions aligned with the pixel output interconnects 826a and 826b. A backplane 850 is formed over the light blocking layer 845. The conductive bridge 849a is formed from a layer of structural material 829 positioned over the substrate. In some implementations, the layer of structural material 829 can be the same layer of structural material used to form the shutters 802a and 802b. The conductive bridge 849a contacts an insulating layer 870 in regions positioned over the pixel output interconnects 826a and 826b. FIG. 8B also shows an adjacent pair of pixel output interconnects 826c and 826d, each associated with a respective display element 800c and 800d included in the same display device as the display elements 800a and 800b. A conductive bridge 849b is positioned above the pixel output interconnects 826c and 826d, and is separated from the pixel output interconnects 826c and 826d by the layer of insulating material 870. Optical windows 880b and 880c also are formed in the light blocking layer 845 above the pixel output interconnects 826c and 826d, respectively. For purposes of the following discussion, it is assumed that the display elements 800c and 800d associated with the pixel output interconnects 826c and 826d, respectively, are both fully operational and therefore do not need to undergo any repair operation.

The conductive bridge 849a is electrically isolated from the pixel output interconnects 826a and 826b by the insulating material 870. In order to electrically connect the shutter 802a of the inoperable display element 800a to the shutter 802b of the functional display element 800b, laser light represented by the arrows 884a and 884b can be directed at the pixel output interconnects 826a and 826b through the optical windows 880a and 880b. The optical windows 880a and 880b can provide an optical path from the substrate 840 to the pixel output interconnects 826a and 826b. In some implementations, the backplane 850 also can be formed from transparent materials that do not interrupt these optical paths. Opaque materials that may be included in the backplane 850 can be etched away in the regions aligned with the optical windows 880a and 880b formed in the light blocking layer 845, so that they do not obstruct the optical paths. The laser light 884a and 884b can ablate the insulating material 870 and can melt the portions of the conductive bridge 849a positioned above the pixel output interconnects 826a and 826b. As a result, the melted portion of the structural material 829 can flow into the space previously occupied by the ablated insulating material 870, thereby forming an electrical connection between the conductive bridge 849a and the pixel output interconnects 826a and 826b. It is not necessary to perform the laser repair operation on the display elements associated with the pixel output interconnects 826c and 826d, because these display elements are both fully operational. Therefore, the pixel output interconnects 826c and 826d both remain electrically isolated from the conductive bridge 849b.

FIG. 8C shows a cross sectional view along the line D-D′ shown in FIG. 8A after the repair operation. As shown, the insulating material 870 has been removed in the regions between the conductive bridge 849a and the pixel output interconnects 826a and 826b, and the conductive bridge 849a is in direct contact with the pixel output interconnects 826a and 826b at the points labeled 899a and 899b, respectively. Therefore the shutter 802a of the inoperable display element 800a is able to receive the voltage applied to the shutter 802b of the functional display element 800b via the conductive bridge 849a. As a result, the inoperable display element 800a can be driven into the same state as the functional display element 800b, which can help to improve image quality. Because the display elements associated with the pixel output interconnects 826c and 826d are both fully operational, the laser repair operation has not been performed on either of these display elements. As a result, the conductive bridge 849b remains electrically isolated from the pixel output interconnects 826c and 826d.

As discussed above, in some implementations the repair operation can be performed by directing laser light through the opposite side of the display device. In such an implementation, optical windows can be formed in a light blocking layer positioned above the EALs 830a and 830b to provide an optical path to the conductive bridge 849a and the pixel output interconnects 826a and 826b. Laser light can be directed along these optical paths through the optical windows formed in a light blocking layer positioned above the EALs 830a and 830b, thereby electrically connecting the conductive bridge 849a to the pixel output interconnects 826a and 826b. The optical windows 880a and 880b formed in the light blocking layer 845 may not be necessary in such an arrangement.

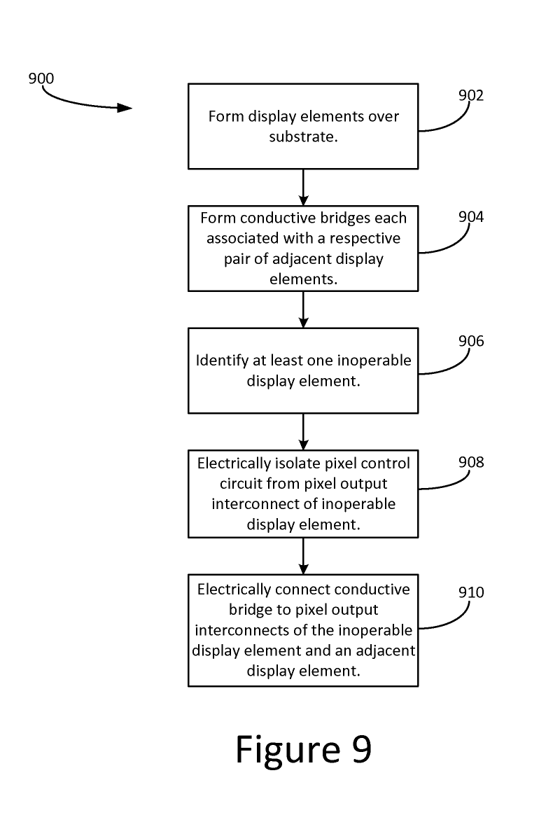

FIG. 9 shows a flow chart of an example process 900 of repairing a display device. In brief overview, the process 900 includes forming a plurality of display elements over a substrate (stage 902) and forming a plurality of conductive bridges each associated with a respective pair of adjacent display elements (stage 904). The process 900 includes identifying at least one inoperable display element (stage 906). A pixel control circuit associated with the inoperable display element can be electrically isolated from the inoperable display element (stage 908). One of the conductive bridges can be electrically connected to the pixel output interconnects of the inoperable display element and an adjacent functional display element (stage 910).

Still referring to FIG. 9, and in greater detail, the process 900 includes forming a plurality of display elements over a substrate (stage 902). In some implementations, each display element can include a shutter, drive beams, load beams, drive anchors, and load anchors similar to those shown in FIG. 5A. In some implementations, a multi-level mold made of a sacrificial material, such as a photodefineable resin, can be formed over the substrate using photolithography. The mold can include surfaces that are parallel to the primary plane of the mold, and sidewalls that are normal to the primary plane of the mold.

After the mold is defined, one or more layers of structural material, such as metals or semiconductors, can be deposited over the mold in one or more conformal deposition processes, such as sputtering, physical vapor deposition (PVD), electroplating, chemical vapor deposition (CVD), plasma-enhanced chemical vapor deposition (PECVD), or atomic level deposition (ALD). Examples of suitable structural materials include, without limitation, a-Si, Ti, and Al. The structural materials can then be etched using one or more etch processes. In some implementations, an anisotropic etch is used to remove undesired portions of the structural material deposited on surfaces of the mold that are parallel to the primary plane of the mold, while leaving structural material on the sidewalls. This material on the sidewalls can form the drive beams as well as the load beams. In some implementations, it also forms the vertical surfaces of the drive anchors and the load anchors. The mold can then be removed through a release process, freeing the remaining components to move.

The process 900 also includes forming a plurality of conductive bridges each associated with a respective pair of adjacent display elements (stage 904). In some implementations, the conductive bridges can be formed from one or more of the layers of structural material used to form the components of the display elements. For example, the layer of structural material used to form shutters of the display elements can also be used to form conductive bridges that intersect portions of pixel output interconnects associated with pairs of adjacent display elements. In some other implementations, the conductive bridges can be formed from metal layers included within a backplane beneath the display elements. In some implementations, the conductive bridges can be initially fabricated such that they are electrically isolated from the pairs of adjacent display elements. For example, for each conductive bridge, one or more layers of dielectric material can be formed between the conductive bridge and at least one of the pixel output interconnects associated with its respective pair of adjacent display elements. Thus, the conductive bridges do not electrically couple their respective pairs of adjacent display elements to one another at this stage. In some implementations, every display element in the display device may be associated with at least one conductive bridge.

The process 900 also includes identifying at least one inoperable display element (stage 906). Inoperable display elements can reduce the quality of images produced by the display device. A display element can be identified as inoperable if the display element is unable to reliably respond to data signals provided to it. For example, if the shutter of a display element fails to move into a closed or open position upon application of an appropriate actuation voltage, the display element can be identified as inoperable.

In some implementations, an optical detection system can be used to identify inoperable display elements. For example, a controller such as the controller 134 shown in FIG. 1A can be configured to cause the drivers 130, 132, and 138, also shown in FIG. 1A, to command each of the display elements to move into a closed position. A backlight can illuminate the display elements from behind the substrate, and an optical detection system, such as a camera, can be used to determine which display elements allow light to pass. Because the display elements have been commanded to move into a closed position, a display element that allows light to pass can be identified as inoperable. In some other implementations, a different system can be used. For example, a system can apply test voltages to a pixel control circuit associated with each display element and can determine whether the output voltages of the pixel control circuits are within an acceptable range. A display element whose pixel control circuit does not output voltages within the acceptable range can be identified as inoperable.

The process 900 also includes electrically isolating a pixel control circuit associated with the inoperable display element from the inoperable display element (stage 908). The inoperable display element can be isolated from the pixel control circuit by cutting a pixel output interconnect that couples the pixel control circuit to the inoperable display element. In some implementations, the pixel output interconnect can be cut using a laser.

Electrically isolating the pixel control circuit associated with the inoperable display element from the inoperable display element can help to improve the performance of the inoperable display element, after the inoperable display element has been electrically connected to an adjacent functional display element. For example, while the pixel control circuit associated with the inoperable display element may not be fully functional, it may still output voltages that could interfere with the voltage received by the inoperable display element from an adjacent display element. Isolating the pixel control circuit associated with the inoperable display element from the inoperable display element can help to avoid this problem.

The process 900 also includes electrically connecting one of the conductive bridges to the pixel output interconnects of the inoperable display element and an adjacent functional display element (stage 910). The reduction in image quality caused by the inoperable display element can be mitigated by driving the inoperable display element into the same state as a neighboring functional display element. Electrically connecting a conductive bridge to the pixel output interconnects of the inoperable display element and an adjacent functional display element allows the inoperable display element to be driven along with the adjacent display element. In some implementations, the conductive bridge can be fused to the pixel output interconnects of both the inoperable display element and the adjacent functional display element to provide an electrical connection between them.

As discussed above, the conductive bridge can initially be electrically isolated from the inoperable display element and the adjacent display element by one or more layers of dielectric material. In some implementations, to electrically connect the pixel output interconnects of the inoperable display element and the adjacent functional display element, a laser can be directed at the intersection of the conductive bridge and the pixel output interconnects of the inoperable display element and the adjacent functional display element. The laser can ablate the dielectric material and can melt the conductive material of either or both of the pixel output interconnects and the conductive bridge. The melted conductive material can flow into the space previously occupied by the dielectric to form an electrical connection between the conductive bridge and the pixel output interconnects of the inoperable display element and the adjacent functional display element so that the inoperable display element can be driven along with the adjacent functional display element.

In some implementations, the display device can include light blocking layers positioned in front of or behind the intersection of the conductive bridge and the pixel output interconnects of the inoperable display element and the adjacent functional display element. In order to permit optical access for the laser, optical windows can be provided in the light blocking layers in regions where the conductive bridge and the pixel output interconnects of the inoperable display element and the adjacent functional display element intersect. In some implementations, the optical windows can be spaced away from the shutter assemblies of the display elements, so that extraneous light is substantially prevented from exiting the display device through the optical windows during normal operation of the display device.

FIG. 10 shows a portion of a pixel control circuit 1060. The pixel control circuit 1060 can be implemented for use in the display apparatus 100 shown in FIGS. 1A and 1B. In some implementations, the pixel control circuit 1060 also can be implemented for use in the display apparatus shown in FIGS. 5A, 5B, 6A-6E, 7A-7C, and 8A-8C, described above.

The pixel control circuit 1060 controls an array of pixels 1062. The pixel control circuit includes a scan-line interconnect 1006 for each row of pixels 1062 and a data interconnect 808 for each column of pixels 1062. A data storage circuit 1020 is controlled by the scan-line interconnect 1006 and the data interconnect 1008. More particularly, the scan-line interconnect 1006 selectively allows data to be loaded into the pixels 1062 of a row by supplying a voltage to the gates of the write-enabling transistors 1030 of the respective pixel control circuits 1060. Each pixel 1062 includes a light modulator 1004. Each light modulator includes a shutter 1007. The shutter 1007 is driven by actuators 1005a and 1005b between a position adjacent the first actuator 1005a and a position adjacent the second actuator 1005b. Each actuator 1005a and 1005b includes a load electrode 1011 and a drive electrode 1009. Generally, as used herein, a load electrode 1011 of an electrostatic actuator corresponds to the electrode of the actuator coupled to the load being moved by the actuator. Accordingly, with respect to the actuators 1005a and 1005b, the load electrode 1011 refers to an electrode of the actuator that couples to the shutter 1007. The drive electrode 1009 refers to the electrode paired with and opposing the load electrode 1011 to form the actuator.

The pixel control circuit 1060 includes a first actuator drive interconnect 1072, a second actuator drive interconnect 1074, and a common ground interconnect 1078. In some implementations, the first actuator drive interconnect 1072 is maintained at a high voltage and the second actuator drive interconnect 1074 is maintained at a low voltage. In some other implementations, the voltages are reversed, i.e., the first actuator drive interconnect 1072 is maintained at a low voltage and the second actuator drive interconnect 1074 is maintained at a high voltage. While the following description of the pixel control circuit 1060 assumes a constant voltage being applied to the first and second actuator drive interconnects 1072 and 1074 (as set forth above), in some other implementations, the voltages on the first actuator drive interconnect 1072 and the second actuator drive interconnects 1074, as well as the input data voltage, are periodically reversed to avoid charge build-up on the electrodes of the actuators 1005a and 1005b.

The common ground interconnect 1078 serves merely to provide a reference voltage for data stored on the data storage capacitor 1035. In some implementations, the pixel control circuit 1060 can forego the common ground interconnect 1078, and instead have the data storage capacitor coupled to the first or second actuator drive interconnect 1072 and 1074.

The pixel control circuit 1060 includes an actuation circuit 1061. The actuation circuit 1061 of the pixel control circuit 1060 includes an update transistor 1040 and a charge transistor 1045. The charge transistor 1045 and the update transistor 1040 are coupled to the load electrode 1011 of the first actuator 1005a of the light modulator 1004 via a pixel output interconnect 1026 (similar to the pixel output interconnects 409, 526, 626, 726, and 826 shown in FIGS. 4, 5A and 5B, 6A-6C, 7A, and 8A-8C, respectively). As a result, when the charge transistor 1045 is activated, an output voltage is present at the source 1088 of the transistor 1045. This output voltage is stored on the load electrodes 1011 of both of the actuators 1005a and 1005b via the pixel output interconnect 1026, as well as on the shutter 1007. Thus, the update transistor 1040, selectively discharges the load electrodes 1011 of the actuators 1005a and 1005b and the shutter 1007 based on received image data, removing the potential on the components.

As indicated above, the first actuator drive interconnect 1072 is maintained at a high voltage and the second actuator drive interconnect 1074 is maintained at a low voltage. Accordingly, while an actuation voltage is stored on the shutter 1007 and the load electrodes 1011 of the actuators 1005a and 1005b, the shutter 1007 moves to the second actuator 1005b, whose drive electrode 1009b is maintained at a low voltage. When the shutter 1007 and the load electrodes 1011 of the actuators 1005a and 1005b are brought to a low voltage, the shutter 1007 moves towards the first actuator 1005a, whose drive electrode 1009a is maintained at a high voltage.

The pixel control circuit 1060 can operate in two general stages. First, data voltages for pixels 1062 in a display are loaded for each pixel 1062, one or more rows at a time, in a data loading stage. In addition, the global update interconnect 1012 is maintained at a high voltage potential to prevent the update transistor 1040 from switching ON during the data loading stage.

After the data loading stage is complete, the shutter actuation stage begins by providing an actuation voltage to the actuation voltage interconnect 1010. By providing the actuation voltage to the actuation voltage interconnect 1010, the charge transistor 1045 is switched ON allowing the current to flow through the charge transistor 1045, bringing the shutter 1007 up to about the actuation voltage. After a sufficient period of time has passed to allow the actuation voltage to be stored on the shutter 1007, the actuation voltage interconnect 1010 is brought low. The amount of time needed for this to occur is substantially less than the time needed for a shutter 1007 to change states. The update interconnect 1012 is brought low immediately thereafter. Depending on the data voltage stored at the data storage capacitor 1035, the update transistor 1040 will either remain OFF or will switch ON.

If the data voltage is high, the update transistor 1040 switches ON, discharging the shutter 1007 and the load electrodes 1011 of the actuators 1005a and 1005b. As a result, the shutter is attracted to the first actuator 1005a. Conversely, if the data voltage is low, the update transistor 1040 remains OFF. As a result, the actuation voltage remains on the shutter and the load electrodes 1011 of the actuators 1005a and 1005b. The shutter, as a result is attracted to the second actuator 1005b.

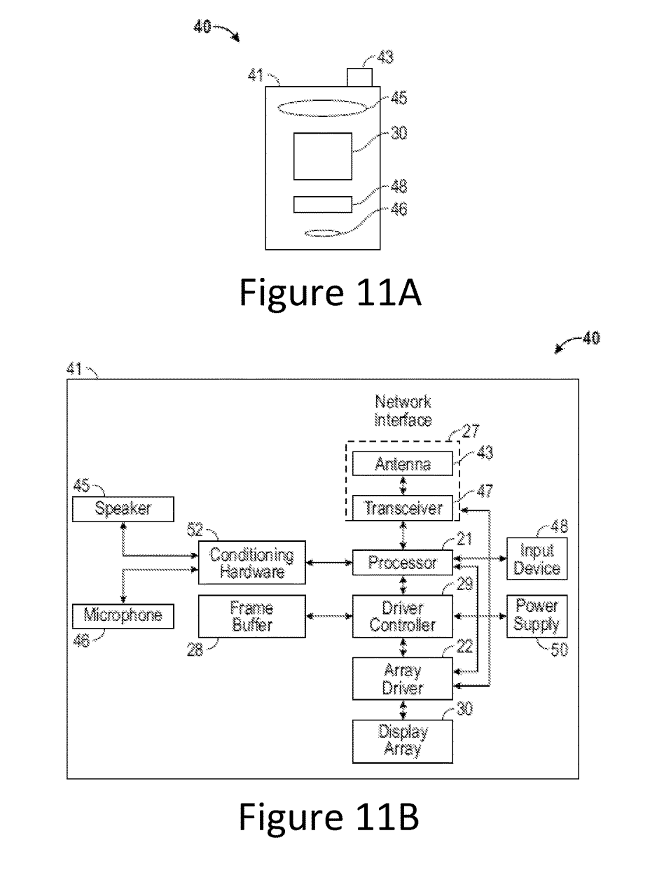

FIGS. 11A and 11B show system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 11B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 11A, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to any of the IEEE 16.11 standards, or any of the IEEE 802.11 standards. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29 is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40. Additionally, in some implementations, voice commands can be used for controlling display parameters and settings.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display device comprising:
a plurality of MEMS display elements over a substrate, each display element including a pixel output interconnect and a pixel control circuit, wherein for at least a first display element:
a pixel control circuit of the first display element is electrically isolated from a pixel output interconnect of the first display element; and
a first conductive bridge includes an electrical connection between the pixel output interconnect of the first display element and a pixel output interconnect of a second display element adjacent the first display element.

2. The display device of claim 1, wherein a voltage applied to the pixel output interconnect of the first display element is based at least in part on a data signal provided to the second display element.

3. The display device of claim 1, wherein at least a portion of the first conductive bridge is closer to a rear surface of the display device than a pixel output interconnect of at least one of its respective pair of adjacent display elements.

4. The display device of claim 1, at least a portion of the first conductive bridge is closer to a front surface of the display device than at least one of the pixel output interconnect of the first display element and the pixel output interconnect of the second display element.

5. The display device of claim 4, wherein the first conductive bridge is within an aperture layer suspended above the plurality of display elements.

6. The display device of claim 1, wherein each display element includes a respective shutter comprising an electrically conductive structural material, and wherein the first conductive bridge includes the same conductive material as the shutters of the plurality of display elements.

7. The display device of claim 6, wherein the electrically conductive structural material includes amorphous silicon.

8. The display device of claim 1, further comprising a second conductive bridge associated with a third display element and a fourth display element adjacent the third display element, wherein the second conductive bridge is separated from the pixel output interconnect of the third display element and the pixel output interconnect of the fourth display element by a dielectric material.

9. The display device of claim 1, further comprising a light blocking layer above or below the plurality of MEMS display elements and the first conductive bridge, wherein the light blocking layer includes at least one optical aperture aligned with an intersection of the first conductive bridge and the pixel output interconnect of the first display element or a load anchor associated with the first display element.

11. The display device of claim 1, wherein each of the plurality of display elements is associated with at least one conductive bridge.

12. The display device of claim 1, further comprising:
a processor capable of communicating with the display device, the processor being capable of processing image data; and
a memory device capable of communicating with the processor.

13. The display device of claim 12, further comprising:
a driver circuit capable of sending at least one signal to the display device; and
a controller capable of sending at least a portion of the image data to the driver circuit.

14. The display device of claim 12, further comprising:
an image source module capable of sending the image data to the processor, wherein the image source module includes at least one of a receiver, transceiver, and transmitter.

15. The display device of claim 12, further comprising:
an input device capable of receiving input data and communicating the input data to the processor.

16. A method of repairing a display device, comprising:
forming a plurality of display elements over a substrate, each display element comprising a pixel control circuit and a pixel output interconnect;
forming a plurality of conductive bridges associated with the pixel output interconnects of adjacent display elements;
identifying at least one inoperable display element of the plurality of display elements, wherein the at least one inoperable display element is unable to respond to a data signal applied by its respective pixel control circuit;
electrically isolating the pixel control circuit of the at least one inoperable display element from the pixel output interconnect of the at least one inoperable display element; and
electrically connecting one of the conductive bridges to the pixel output interconnect of the at least one inoperable display element and the pixel output interconnect of an adjacent display element.

17. The method of claim 16, wherein electrically isolating the pixel control circuit of the at least one inoperable display element from the pixel output interconnect of the at least one inoperable display element comprises ablating a portion of the pixel output interconnect of the at least one inoperable display element to cut the pixel output interconnect of the at least one inoperable display element.

18. The method of claim 17, wherein electrically connecting one of the conductive bridges to the pixel output interconnect of the at least one inoperable display element and the pixel output interconnect of an adjacent display element comprises directing electromagnetic radiation at the conductive bridge to:
ablate a dielectric material separating the conductive bridge from the pixel output interconnects of the at least one inoperable display element and the adjacent display element; and
melt a portion of the conductive bridge or the pixel output interconnects of the at least one inoperable display element and the adjacent display element such that the melted portion fills a space previously occupied by the ablated dielectric material to form an electrical connection between the conductive bridge and the pixel output interconnects of the at least one inoperable display element and the adjacent display element.

19. The method of claim 17, wherein forming the plurality of conductive bridges comprises forming the conductive bridges within an aperture layer of the display device.

20. The method of claim 16, further comprising:
forming a light blocking layer above or below the plurality of display elements and the plurality of conductive bridges; and
forming at least one optical aperture in the light blocking layer, the at least one optical aperture aligned with an intersection of a conductive bridge and a pixel output interconnect of a display element.

21. The method of claim 16, wherein:
forming the plurality of display elements further comprises forming a respective shutter associated with each display element, the shutters comprising an electrically conductive structural material; and
forming the plurality of conductive bridges further comprises forming at least one conductive bridge from the same conductive material as the shutters.

22. The method of claim 16, wherein each of the plurality of display elements is associated with at least one conductive bridge.

23. A display device comprising:
a plurality of MEMS display elements over a substrate, each display element including an output voltage carrying means and a control means, wherein:
a control means of the first display element is electrically isolated from an output voltage carrying means of the first display element; and
a first conductive means includes an electrical connection between the output voltage carrying means of the first display element and an output voltage carrying means of a second display element adjacent the first display element.

24. The display device of claim 23, wherein a voltage applied to the output voltage carrying means of the first display element is based at least in part on a data signal provided to the second display element.

25. The display device of claim 23, wherein the first conductive means is within an aperture layer suspended above the plurality of MEMS display elements.

26. The display device of claim 23, wherein each display element includes a respective light blocking means comprising an electrically conductive structural material, and wherein the first conductive means includes the same conductive material as the light blocking means of the plurality of display elements.

27. The display device of claim 26, wherein the electrically conductive structural material includes amorphous silicon.

28. The display device of claim 23, further comprising a second conductive means associated with a third display element and a fourth display element adjacent the third display element, wherein the second conductive means is separated from the output voltage carrying means of the third display element and the output voltage carrying means of the fourth display element by a dielectric material.

29. The display device of claim 23, further comprising a light blocking layer above or below the plurality of MEMS display elements and the first conductive means, wherein the light blocking layer includes at least one optical aperture aligned with an intersection of the first conductive means and the output voltage carrying means of the first display element or a load anchor associated with the first display element.

30. The display device of claim 23, wherein each of the plurality of MEMS display elements is associated with at least one conductive means.
